(19) United States
(12) Patent Application Publication
(10) Pub. No.: US 2007/0181880 A1
(43) Pub. Date: Aug. 9, 2007

(54) SEMICONDUCTOR DEVICE AND METHOD FOR FORMING THE SAME

(75) Inventor: Sung-Bong KIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/672,893

(22) Filed: Feb. 8, 2007

(30) Foreign Application Priority Data
Feb. 8, 2006 (KR) 10-2006-0012276

(51) Int. Cl. H01L 29/10; H01L 21/84

(52) U.S. Cl. 257/67; 438/152; 257/E25.013

(57) ABSTRACT

A semiconductor device includes a conductive layer formed on a semiconductor substrate. An insulation layer is formed on the conductive layer and includes an opening defined therein that exposes the conductive layer. A semiconductor pattern is formed on the insulation layer and is electrically connected to the conductive layer through the opening. A transistor is formed on the semiconductor pattern.

### CROSS-REFERENCE TO RELATED APPLICATIONS

This patent application claims the benefit of foreign priority to Korean Patent Application No. 10-2006-0012276, filed on Feb. 8, 2006, the entire contents of which are hereby incorporated by reference.

### BACKGROUND

1. Field of Invention

Exemplary embodiments described herein relate generally to semiconductor devices and methods for forming the same and, more particularly, to a semiconductor device having a silicon on insulator (SOI) structure and a method for forming the same.

2. Description of the Related Art

Semiconductor devices are largely classified as either a bulk-type semiconductor device or a SOI-type semiconductor device. A bulk-type semiconductor device, e.g., a bulk-type transistor, is a plane-type device formed on an active region of a semiconductor substrate such as a single-crystal silicon substrate. There is a limitation in forming a highly integrated semiconductor device as a bulk-type semiconductor device. As the degree of integration in a semiconductor device increases, a channel length of a metal oxide silicon (MOS) transistor decreases. Therefore, problems such as a short channel effect, a high parasitic junction capacitance, and inefficiency of device isolation occur. Accordingly, there is a limit to which a high degree of integration can be achieved in a conventional bulk-type device.

On the other hand, a SOI-type device is disposed on a buried insulating layer to form a MOS transistor on a thin semiconductor layer insulated from a bulk substrate. In a device, e.g., a static random access memory (SRAM), requiring multi-layered transistors stacked on a substrate to achieve the high degree of integration, the transistors are generally SOI transistors. The SOI transistor has superior device isolation, lower parasitic junction capacitance, and more alleviated short channel effect compared to a bulk-type semiconductor device.

However, a conventional SOI substrate is relatively more expensive to manufacture than a bulk substrate. Additionally, a SOI device floats since a semiconductor layer having the SOI device is isolated by a base bulk substrate and a buried insulating layer. Therefore, floating body effects such as current and voltage kinks, threshold voltage variation, and heat deterioration occur. Accordingly, the conventional SOI device requires the reduction of the floating body effect. Moreover, the conventional SOI device requires a method for achieving the high degree of integration.

### SUMMARY

Exemplary embodiments described herein provide a SOI device capable of reducing a floating body effect, and a method for forming the same. Other example embodiments described herein provide a highly integrated semiconductor device and a method for forming the same.

One embodiment disclosed herein can be exemplarily characterized as a method for forming a semiconductor device. In the method, a conductive layer and an insulation layer are formed on a semiconductor substrate. A first opening is formed within the insulation layer to expose the conductive layer. A semiconductor pattern is formed on the insulation layer and is electrically connected to the conductive layer through the first opening. A transistor is also formed that includes the semiconductor pattern. A body contact is also formed to be electrically connected to the conductive layer.

Another embodiment disclosed herein can be exemplarily characterized as a method for forming a semiconductor device in which a first transistor and an interlayer insulation layer are formed on a single-crystal region of a semiconductor substrate. A polycrystalline conductive layer and an insulation layer are formed on the interlayer insulation layer. A first opening is formed through the insulation layer to expose the polycrystalline conductive layer. A second opening is formed through the insulation layer and the interlayer insulation layer to expose the single-crystal region of the semiconductor substrate. A first plug is formed within the first opening and is electrically connected to the polycrystalline conductive layer. A second plug is formed within the second opening according to an epitaxial growth method. A single-crystal semiconductor pattern is formed on the first and second plugs and the insulation layer. A second transistor is formed on the single-crystal semiconductor pattern.

Another embodiment disclosed herein can be exemplarily characterized as a method of Forming a semiconductor device in which a semiconductor substrate having a single-crystal region and a first transistor formed thereon are provided. An interlayer insulation layer is formed on the semiconductor substrate, wherein the interlayer insulation layer includes a first opening defined therein exposing the single-crystal region. A single-crystal plug is formed within the first opening. A conductive layer is formed on the single-crystal plug and on the interlayer insulation layer. An insulation layer is formed on the conductive layer, wherein the insulation layer includes a second opening exposing the conductive layer and a third opening exposing the single-crystal plug. A single-crystal semiconductor pattern is formed within the second and third openings and on the insulation layer. A second transistor is formed on the single-crystal semiconductor pattern.

Yet another embodiment disclosed herein can be exemplarily characterized as a semiconductor device in which a conductive layer is on a semiconductor substrate. An insulation layer is on the conductive layer. A semiconductor pattern is on the insulation layer. A first plug is within the insulation layer and electrically connects the conductive layer to the semiconductor pattern. A first transistor of the semiconductor device includes the semiconductor pattern. Additionally, a body contact is electrically connected to the conductive layer.

Yet another embodiment disclosed herein can be exemplarily characterized as a silicon-on-insulator (SOI) semiconductor device that includes a semiconductor substrate and at least one SOI structure over the semiconductor substrate. The SOI structure may include a conductive pattern, an insulation layer on the conductive pattern, a semiconductor pattern on the insulation layer electrically connected to the conductive pattern through the insulation layer, and a transistor comprising the semiconductor pattern. Additionally, a body contact may be electrically connected to the conductive layer.

### BRIEF DESCRIPTION OF THE FIGURES

The accompanying figures are included to provide a further understanding of exemplary embodiments, and are incorporated in and constitute a part of this specification. The drawings illustrate exemplary embodiments and, together with the description, serve to explain principles of the present invention. In the figures:

FIG. 1 is a sectional view of a first exemplary embodiment of a semiconductor device;

FIGS. 2 through 4 are plan views of various embodiments of the semiconductor device shown in FIG. 1;

FIGS. 5 through 9 are sectional views illustrating a first exemplary method of forming a semiconductor device;

FIGS. 10 through 14 are sectional views illustrating a second exemplary method of forming a semiconductor device; and

FIG. 15 is a sectional view illustrating a second exemplary embodiment of a semiconductor device.

### DETAILED DESCRIPTION OF THE ILLUSTRATED EMBODIMENTS

Exemplary embodiments will be described below in more detail with reference to the accompanying drawings. The exemplary embodiments may, however, be realized in different forms and should not be constructed as limited to the embodiments set forth herein. Rather, these embodiments are provided so that this disclosure will be thorough and complete, and will fully convey the scope of the present invention to those skilled in the art.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

It will be also understood that, although the terms first, second, third, and the like may be used herein to describe various elements, components, regions, layers, sections, voltages, and the like, these elements, components, regions, layers, sections, and voltages should not be limited by these terms. These terms are only used to distinguish one element, component, region, layer, section, and voltage from another element, component, region, layer, section, and voltage. Thus, a first element, component, region, layer, section, and voltage mentioned in one embodiment could be termed a second element, component, region, layer, section, and voltage in another embodiment without departing from the teachings of the present invention. Moreover, a semiconductor substrate, a semiconductor layer, or a semiconductor pattern mentioned in the example embodiments may include a silicon substrate, a silicon-germanium substrate, a doped or undoped silicon substrate, an epitaxial layer using an epitaxial growth technology, and another semiconductor substrate.

Exemplary embodiments described herein relate generally to semiconductor devices such as silicon on insulator (SOI) devices. The SOI device exemplarily disclosed may be utilized in various devices (e.g., in semiconductor devices having a plurality of transistors that are stacked on a substrate). For example, a semiconductor device such as a static random access memory (SRAM) device includes a plurality of transistors stacked on a substrate. By way of example, a full complementary metal oxide semiconductor (CMOS)SRAM device includes six transistors. The degree of integration of the CMOS SRAM device may be increased by stacking the six transistors on the substrate.

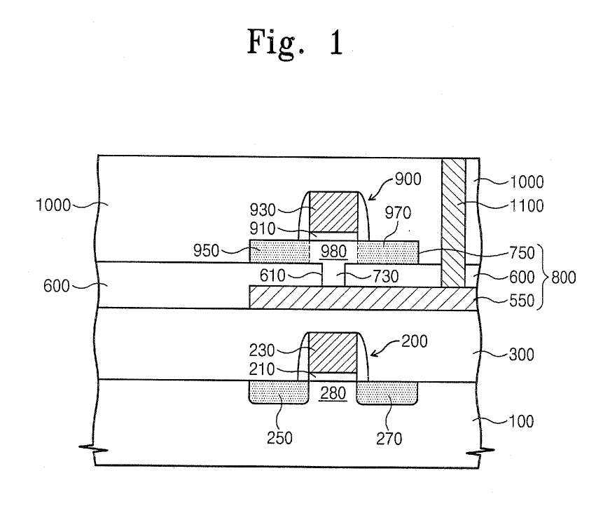

FIG. 1 is a sectional view of a first exemplary embodiment of a semiconductor device.

Referring to FIG. 1, a SOI structure 800 is disposed on a bulk substrate 100. The SOI structure 800 is insulated from the bulk substrate 100 by a first interlayer insulation layer 300. Accordingly, the first interlayer insulation layer 300 is interposed between the bulk substrate 100 and the SOI structure 800.

A first transistor 200 (e.g., an n-type transistor) may be formed on an active region of the bulk substrate 100 and a second transistor 900 (e.g., a p-type transistor) may be disposed on the SOI structure 800. The second transistor 900 includes a gate electrode 930 on a semiconductor pattern 750 of the SOI structure 800. A gate insulation layer 910 is interposed between the gate electrode 930 and the semiconductor pattern 750. A source 950 and a drain 970 are formed in the semiconductor pattern 750 at both sides of the gate electrode 930. The portion of the semiconductor pattern 750 under the gate electrode 930 and between the source and the drain 950 and 970 serves as a channel region 980. Likewise, the first transistor 200 includes a gate electrode 230 on an active region of the bulk substrate 100. A gate insulating layer 210 is interposed between the gate electrode 230 and the active region of the bulk substrate 100. A source 250 and a drain 270 are formed in the active region at both sides of the gate electrode 230. The portion of the active region of the bulk substrate 100 between the source and the drain 250 and 270 serves as a channel region 280.

According to the illustrated embodiment, the SOI structure 800 includes a conductive layer 550 serving as a base (or bulk) substrate, an insulation layer 600 serving as a buried insulating layer, and the semiconductor pattern 750 serving as an active region. The semiconductor pattern 750 and the conductive layer 550 are electrically connected to each other through a plug 730 penetrating an opening 610 of the insulation layer 600. The conductive layer 550 may include a material such as, for example, polycrystalline silicon doped with an n-type impurity. The semiconductor pattern 750 may include a material such as, for example, single-crystal silicon.

A body contact 1100 is formed in a second interlayer insulating layer 1000 and the insulating layer 600 to be electrically connected to the conductive layer 550. When a bias voltage is applied to the conductive layer 550 serving as a bulk substrate through the body contact 1100, the electric potential is uniformly maintained in a channel region 980 of the semiconductor pattern 750.

For semiconductor devices in various fields, the SOI structure 800 and related transistors shown in FIG. 1 are perpendicularly stacked with respect to the surface of the semiconductor substrate 100.

If the body contact 1100 is formed on the semiconductor pattern 750, the semiconductor pattern 750 needs to be formed very thick to provide a suitable body contact region. Such a thickness makes it difficult to form a complete depletion-type transistor. Additionally, when the body contact 1100 is formed on a semiconductor layer, an additional body contact region for the body contact and an isolation insulating layer for the body contact region are required. This makes it difficult to achieve the high degree of integration. According to the illustrated embodiment, however, because the body contact 1100 is formed on the conductive layer 550, the semiconductor pattern 750 can be formed very thin. Therefore, the second transistor 900 may be provided as a complete depletion type transistor.

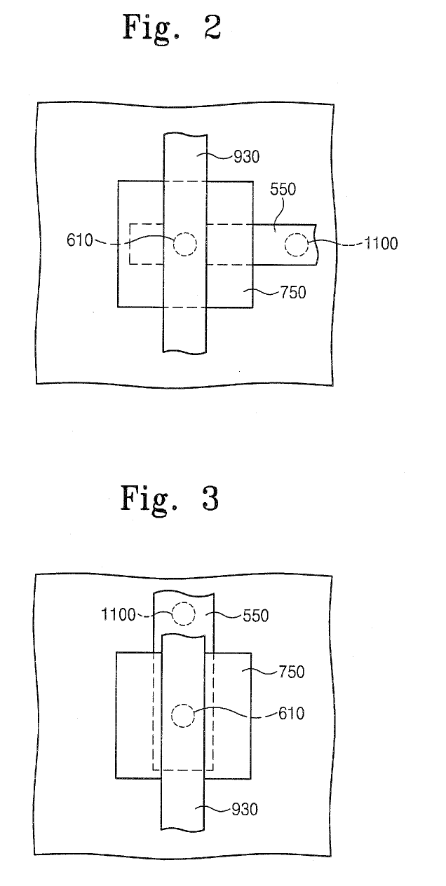

Furthermore, relative configurations of the conductive layer 550 and the semiconductor pattern 750 can be advantageously selected with respect to other elements. This will be described with reference to FIGS. 2 through 4.

FIGS. 2 through 4 are plan views of various embodiments of the semiconductor device shown in FIG. 1.

Referring to FIG. 2, a gate electrode 930 of the second transistor 900 extends above the semiconductor pattern 750 along a first direction. The conductive layer 550 extends below the semiconductor pattern 750 along a second direction (e.g., substantially perpendicular to the first direction) that crosses the first direction and is electrically connected to the semiconductor pattern 750 through the opening 610 of the insulation layer 600. Alternatively, and as illustrated in FIG. 3, the conductive layer 550 and gate electrode 930 extend along substantially the same direction (i.e., the conductive layer 550 and gate electrode 930 are substantially parallel).

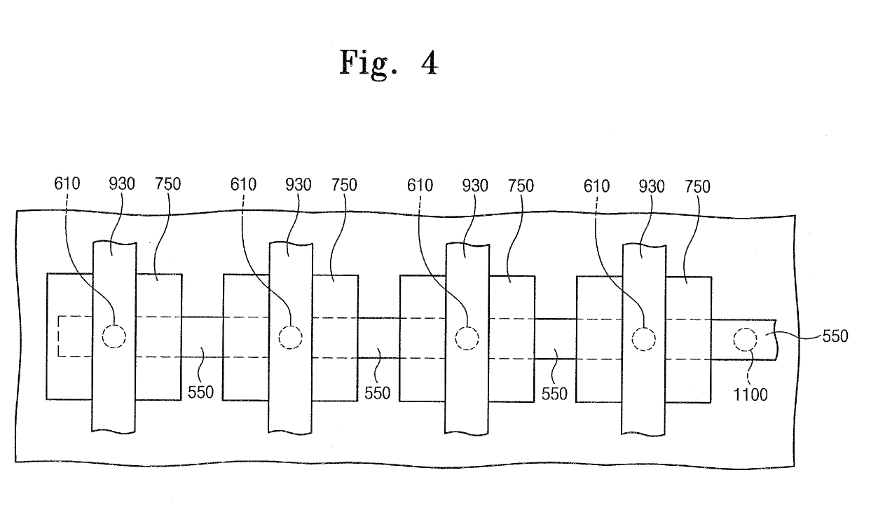

In one embodiment, a plurality of SOI structures may be horizontally formed in an identical layer. In such an embodiment, each individual SOI structure includes a conductive layer 550, or, as exemplarily illustrated in FIG. 4, horizontally adjacent SOI structures may share the same conductive layer 550. A higher degree of integration can be achieved when forming one conductive layer 550 for multiple horizontally adjacent SOI structures as compared to forming separate conductive layers 550 for each individual SOI structure. When forming separate conductive layers 550, a body contact 1100 needs to be formed on each conductive layer. However, when adjacent SOI structures share one conductive layer 550, only one body contact 1100 needs to be formed.

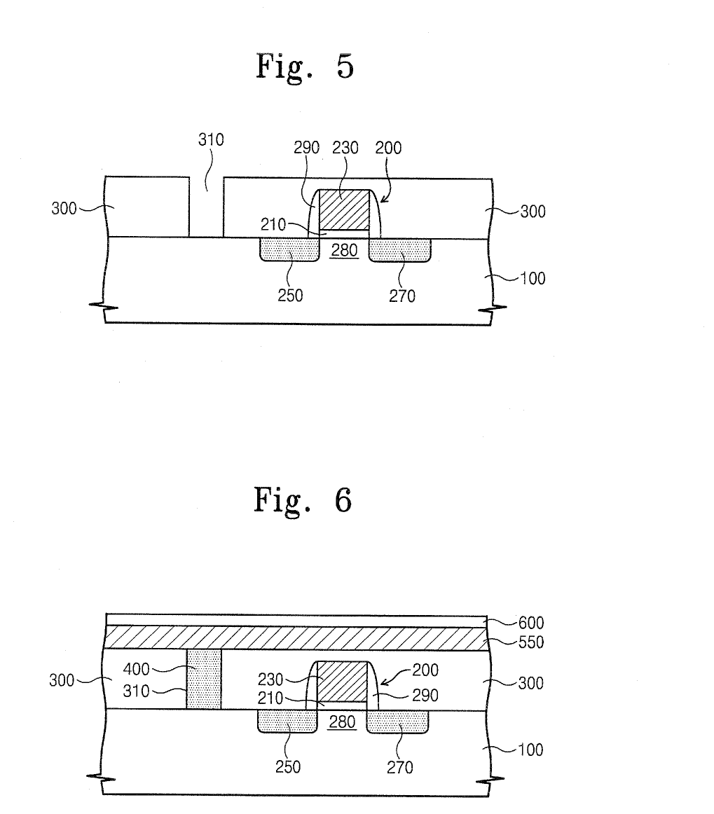

FIGS. 5 through 9 are sectional views illustrating a first exemplary method of forming a semiconductor device.

Referring to FIG. 5, a first transistor 200 (e.g., an n-type transistor) is formed on a semiconductor substrate 100 (e.g., on a single-crystal active region of semiconductor substrate 100). The semiconductor substrate 100 may include a silicon substrate, a silicon-germanium substrate, a doped or undoped silicon substrate, an epitaxial layer using an epitaxial growth technology, or another semiconductor substrate. In the illustrated embodiment, the semiconductor substrate 100 is a single-crystal silicon substrate. A thin film such as polycrystalline silicon, tungsten silicide, metal material, or a combination thereof is formed and patterned to form a gate electrode 230 of the first transistor 200. A source 250 and a drain 270 of the first transistor 200 may be formed by implanting impurities (e.g., ions) after forming the gate 230. The gate insulation layer 210 may be formed using, for example, a thermal oxide process or a chemical vapor deposition (CVD) process. Additionally, insulation spacers 290 are formed on sidewalls of the gate 230. When the conductive type of the semiconductor substrate 100 is a p-type, impurities in the source 250 and the drain 270 are an n-type.

A first interlayer insulation layer 300 is formed over the first transistor 200. The first interlayer insulation layer includes a second opening 310 defined therein and expose a single-crystal active region of a semiconductor substrate 100.

The first interlayer insulation layer 300 may be provided as a single insulation layer or a multi-layer insulation layer using a well-known method such as a CVD method, a physical vapor deposition (PVD) method, or a spin-on-glass (SOG) method.

Referring to FIG. 6, a plug 400 is formed to fill the second opening 310. A conductive layer 550 is formed on the plug 400 and the first interlayer insulation layer 300. The plug 400 may, for example, be formed according to an epitaxial growth method in which single-crystal silicon is grown using the single-crystal silicon of the semiconductor substrate 100 as a seed layer. For example, a silicon epitaxial growth method may use a silicon source gas such as SiH₂Cl₂, SiHCl₃, and SiCl₄ at a temperature of 800° C. The conductive layer 550 may include a material such as, for example, polycrystalline silicon formed according to a CVD method, or amorphous or single-crystal silicon by appropriately controlling a reaction speed. A chemical mechanical polishing (CMP) process can be additionally performed to planarize the top of the single-crystal silicon plug 400.

Referring still to FIG. 6, an insulation layer 600 is formed on the conductive layer 550. The insulation layer 600 may include a material such as, for example, silicon oxide formed according to a CVD method. In another embodiment, the insulation layer 600 may be formed by oxidizing a portion of conductive layer 550 including polycrystalline silicon.

An impurity implantation process is performed to dope the conductive layer 550 with a p-type impurity. In one embodiment, an appropriate ion implantation mask may be used to selectively implant n-type or p-type impurities into predetermined regions of the conductive layer 550. For example, the conductive layer 550 may be doped with an n-type impurity in a region where a p-type second transistor is to be subsequently formed and may be doped with a p-type impurity in a region where an n-type second transistor is to be subsequently formed.

In one embodiment, a photolithography process may be performed to pattern the conductive layer 550 in a desired shape. The photolithography process for the conductive layer 550 can be performed before or after forming the insulation layer 600. Although not show in FIG. 6, a photolithography process can be performed to isolate the conductive layer 550 from the plug 400.

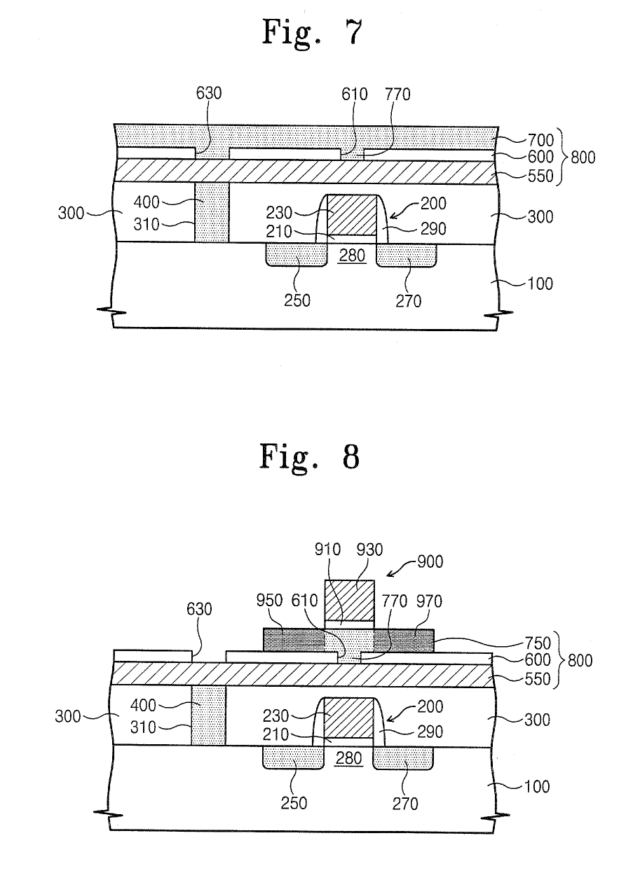

Referring to FIG. 7, the insulation layer 600 is patterned to form a first opening 610 exposing a first portion of the conductive layer 550 and a third opening 630 exposing a second portion of the conductive layer 550 on the silicon plug 400. A semiconductor layer 700 is formed within the first opening 610, within the third opening 630 and on the insulation layer 600. The conductive layer 550, the insulating layer 600 and the semiconductor layer 700, connected to the conductive layer 550 through the first and third openings 610 and 630, forms a SOI structure 800. The semiconductor layer 700 may include a single-crystal semiconductor (e.g., silicon) layer. In one embodiment, the semiconductor layer 700 may be formed by forming polycrystalline silicon within the first opening 610 and the third opening 630 and on the insulation layer 600 according to a CVD method. Then, the polycrystalline silicon may be crystallized (i.e., recrystallized) to form single-crystal silicon. In one embodiment, the polycrystalline silicon may be crystallized into single-crystal silicon according to a heating process (e.g., an annealing process, a laser treatment, or the like). In the heating process, the single-crystal silicon plug 400 may be used as a seed layer for crystallization. A plug portion 770 of the semiconductor layer 700 in the first opening 610 is electrically connected to the conductive layer 550.

Referring to FIG. 8, the semiconductor layer 700 is patterned to form a semiconductor pattern 750 (i.e., a single-crystal semiconductor pattern) and then a gate insulation layer 910 and a gate electrode 930 are formed. A p-type impurity is implanted into the semiconductor pattern 750 at both sides of the gate electrode 930 to form a source 950 and a drain 970, thereby fabricating a second transistor 900 as a p-type transistor.

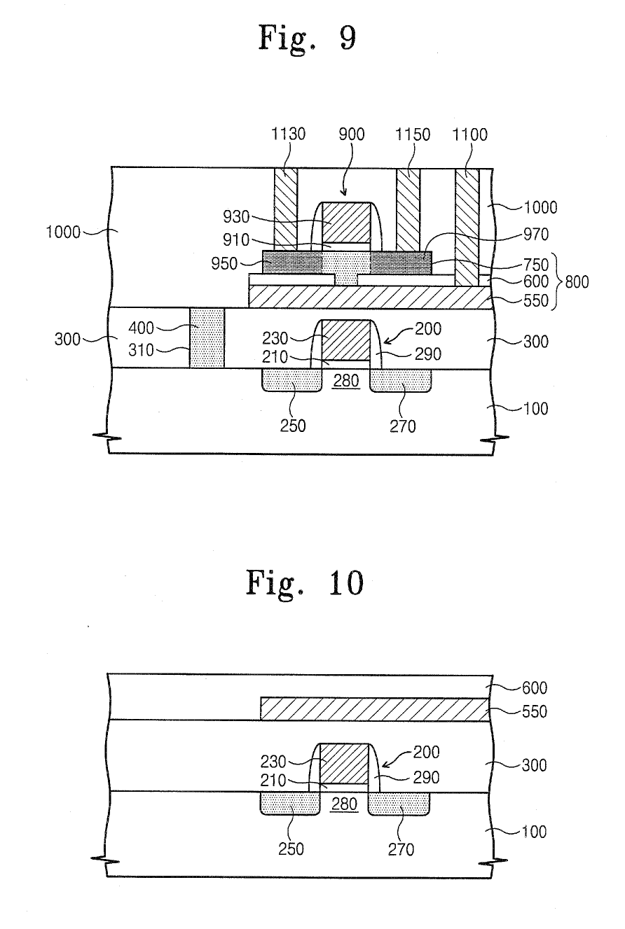

Referring to FIG. 9, a second interlayer insulation layer 1000 is formed. The second interlayer insulation layer 1000 can be formed, for example, using the same method as was used to form the first interlayer insulation layer 300. A body contact 1100 is formed to electrically connect to the polycrystal silicon conductive layer 550 through the second interlayer insulation layer 1000 and the insulation layer 600. To form the body contact 1100, the second interlayer insulation layer 1000 and the insulation layer 600 are patterned to form a body contact hole and a material such as tungsten is formed within the body contact hole. In one embodiment, a source contact 1130 connected to the source 950 and a drain contact 1150 connected to the drain 970 may also be formed in the manner described above with respect to the body contact 1100. In one embodiment, the source contact 1130 and the drain contact 1150 may be formed when the body contact 1100 is formed.

The conductive layer 550 may be patterned to electrically insulate the polycrystal silicon conductive layer 550 from the single-crystal silicon plug 400. For example, the insulation layer 600 and the conductive layer 550 may be patterned to expose the plug 400 after the semiconductor layer 700 is patterned to form the semiconductor pattern 750.

In one embodiment, the plug 400 and the conductive layer 550 shown in FIG. 2 can be simultaneously formed (e.g., according to a CVD method). In such an embodiment, the plug 400 and conductive layer 550 may be single-crystal silicon, amorphous silicon, or polycrystalline silicon depending on, for example, a deposition temperature. A crystallization process may be performed on deposited amorphous or polycrystalline silicon to form single-crystal silicon, in which the active region of the semiconductor substrate 100 may serve as a seed layer. Further, the plug 400 and the conductive layer 550 shown in FIG. 2 can be single-crystal silicon formed according to, for example, an epitaxial growth process. In this case, a CMP process may be performed to planarize the top of the resultant single-crystal silicon on the first interlayer insulation layer 200.

As described above with respect to FIGS. 5 through 9, a plug 400 may be formed prior to formation of the conductive layer 550. However, formation of the plug 400 is not limited to the method exemplarily described above. Accordingly, FIGS. 10 through 14 are sectional views illustrating a second exemplary method of forming a semiconductor device.

Referring to FIG. 10, a first transistor 200 (e.g., an n-type transistor) may be formed according to the method exemplarily described above with respect to FIGS. 5 through 9. A first interlayer insulation layer 300 is then formed on the semiconductor substrate 100 to cover the first transistor 200. A conductive layer 550 is formed on the first interlayer insulation layer 300, and an insulation layer 600 is formed on the first interlayer insulation layer 300 and the conductive layer 550. To form the conductive layer 550, a material such as, for example, polycrystalline silicon doped with an n-type can be formed and subsequently patterned into a desired shape that exposes a portion of the first interlayer insulation layer 300. The insulation layer 600 may include a material such as, for example, silicon oxide formed according to a CVD method.

Referring to FIG. 11, the insulation layer 600 is patterned to form a first opening 610 exposing the conductive layer 550. Additionally, the insulation layer 600 and the first interlayer insulation layer 300 exposed by the conductive layer 550 are patterned to form a fourth opening 640 exposing the active region (e.g., a single-crystal region) of the semiconductor substrate 100.

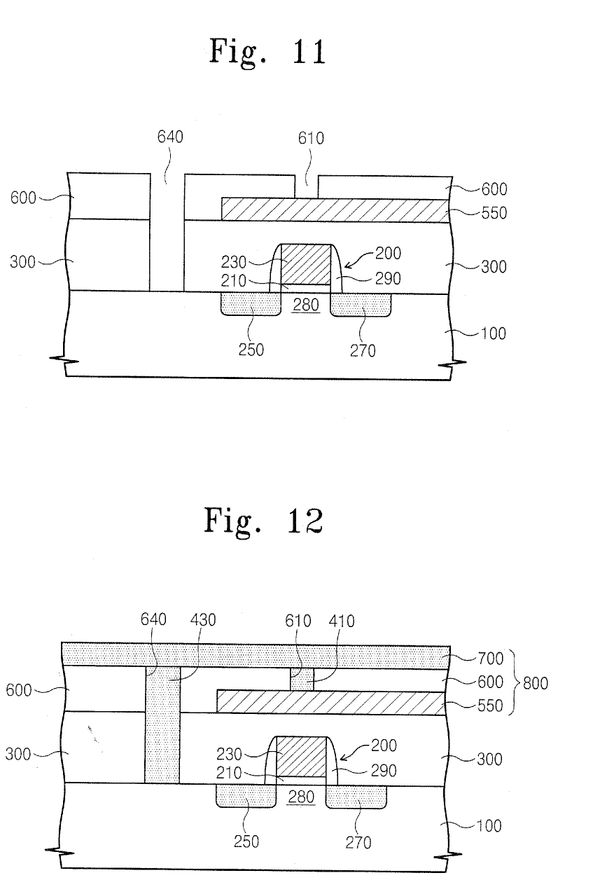

Referring to FIG. 12, a first plug 410 is formed to fill the first opening 610 and a second plug 430 is formed to fill the fourth opening 640 according to an epitaxial growth method. In one embodiment, the first plug 410 may include a material such as, for example, polycrystalline silicon and second plug 430 may include a material such as, for example, single-crystal silicon. In a further embodiment, the epitaxial growth method employed may be the same as the epitaxial growth method described above with respect to FIGS. 6 through 9.

A semiconductor layer 700 is then formed on the first plug 410, on the second plug 430 and on the insulation layer 600. The conductive layer 550, the insulating layer 600 and the semiconductor layer 700, connected to the conductive layer 550 through the first opening 610, form the SOI structure 800. The semiconductor layer 700 can be formed according to the same methods as described above with respect to FIG. 7. For example, the semiconductor layer 700 may be initially formed of a polycrystalline silicon material and subsequently crystallized in a heating process using the single-crystal silicon second plug 430 to form a single-crystal silicon semiconductor layer 700.

Referring to FIG. 13, the semiconductor layer 700 is patterned to form a semiconductor pattern 750 exposing the second plug 430 and then a second transistor 900 (e.g., a p-type transistor) is formed. Spacers 990 are formed on both sides of the gate electrode 930 of the transistor 900.

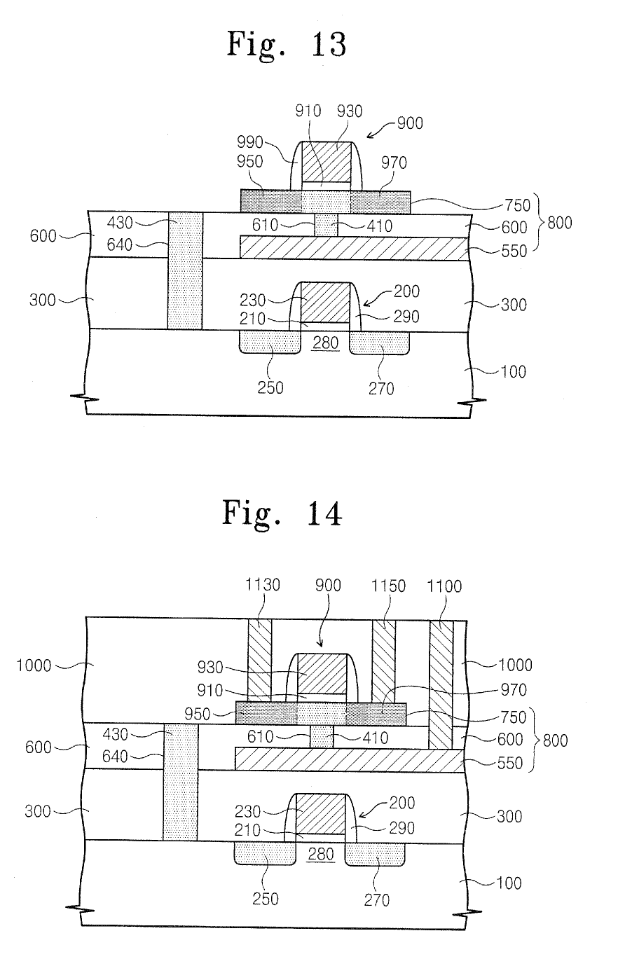

Referring to FIG. 14, a body contact 1100, a source contact 1130 and a drain contact 1150 are formed after forming a second insulation layer 1000.

Although not illustrated in the FIGS. above, the semiconductor pattern 750 can be patterned so as to be connected to the second plug 430. Such a configuration may be desirable when the first and second transistors 200 and 900 have the same conductivity-type and need to be connected to each other. Accordingly, the first and second transistors 200 and 900 may be easily connected to each other by patterning the semiconductor layer 700, without the need for an additional contact process.

In one embodiment, an epitaxial silicon layer may be formed in the first opening 610 and the fourth opening 640 and on the insulation layer 600 using an epitaxial growth method, and a crystallization process may be performed after a planarization process to form the first plug 410, the second plug 430 and the semiconductor layer 700. In such an embodiment, a planarization process and/or a crystallization process may not be performed.

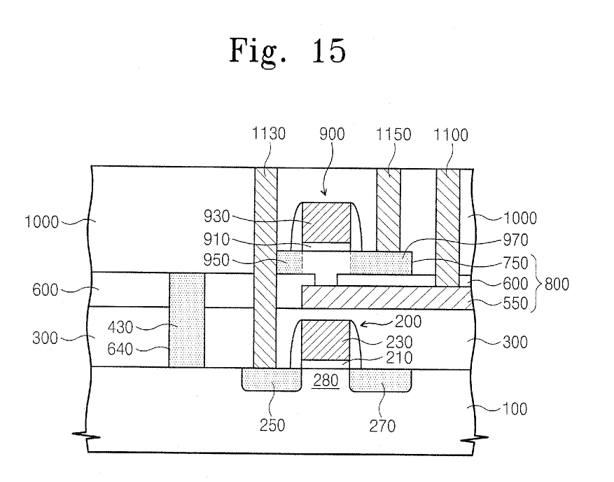

FIG. 15 is a sectional view illustrating a second exemplary embodiment of a semiconductor device.

The semiconductor device shown in FIG. 15 may be formed according to the method exemplarily described above with respect to FIGS. 10 through 14. As illustrated in FIG. 15, however, the source contact 1130 may be formed to simultaneously connect the source 250 of the first transistor 200 and the source 950 of the second transistor 900. In this case, the conductive layer 550 does not extend to the source 250 of the first transistor 200 and the source 950 of the second transistor 900 as shown in FIG. 14.

In the embodiments described with reference to FIGS. 5 through 15, the configuration of a conductive layer 550 (e.g., via patterning of the conductive layer), the configuration of the semiconductor pattern 750 (e.g., via patterning of the semiconductor layer 700), the positions of the source and drain contacts (e.g., via positions of contact holes) and a gate electrode can be modified to facilitate electrical connection between components in a semiconductor device. Thus, according to the embodiments described above, a semiconductor device having a high degree of integration can be achieved. Moreover, a SOI semiconductor device (e.g., transistor) can be formed while avoiding a floating body effect. Further, a SOI semiconductor device (e.g., transistor) can be manufactured economically.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method for forming a semiconductor device, the method comprising:
forming a conductive layer and an insulation layer on a semiconductor substrate;
forming a first opening within the insulation layer, the first opening exposing the conductive layer;
forming a semiconductor pattern on the insulation layer, the semiconductor pattern electrically connected to the conductive layer through the first opening;
forming a transistor, wherein the transistor comprises the semiconductor pattern; and
forming a body contact electrically connected to the conductive layer.

2. The method of claim 1, further comprising:
forming a bottom interlayer insulation layer on the semiconductor substrate before forming the conductive layer; and
forming a second opening through the insulation layer and the bottom interlayer insulation layer, the second opening exposing an active region of the semiconductor substrate.

3. The method of claim 2, wherein forming the semiconductor pattern comprises:
forming a semiconductor layer within the first and second openings and on the insulation layer;
crystallizing the semiconductor layer; and
patterning the crystallized semiconductor layer.

4. The method of claim 2, wherein forming the semiconductor pattern comprises:
forming plugs within the first and second openings;
forming a semiconductor layer on the plugs and on the insulation layer;
crystallizing the semiconductor layer; and
patterning the crystallized semiconductor layer.

5. The method of claim 4, wherein forming the plugs comprises forming a single-crystal material within the second opening and forming a polycrystalline material within the first opening.

6. The method of claim 1, further comprising:
forming a bottom interlayer insulation layer on the semiconductor substrate before forming the conductive layer;
forming a second opening within the bottom interlayer insulation layer, the second opening exposing an active region of the semiconductor substrate;
forming a plug comprising a single-crystal material within the second opening; and
forming a third opening within the insulation layer, the third opening exposing the plug, wherein
forming the conductive layer comprises forming the conductive layer on the plug and on the bottom interlayer insulation layer.

7. The method of claim 6, wherein forming the semiconductor pattern comprises:
forming a semiconductor layer within the first and third openings and on the insulation layer;
crystallizing the semiconductor layer; and
patterning the crystallized semiconductor layer.

8. The method of claim 7, wherein forming the conductive layer and the insulation layer comprises:
forming a polycrystalline material layer on the semiconductor substrate;
forming an oxide layer on the polycrystalline material layer; and
introducing impurities into the polycrystalline material layer.

9. A method for forming a semiconductor device, the method comprising:
forming a first transistor and an interlayer insulation layer on a single-crystal region of a semiconductor substrate;
forming a polycrystalline conductive layer and an insulation layer on the interlayer insulation layer;
forming a first opening through the insulation layer, the first opening exposing the polycrystalline conductive layer;
forming a second opening through the insulation layer and the interlayer insulation layer, the second opening exposing the single-crystal active region of the semiconductor substrate;
forming a first plug within the first opening, the first plug electrically connected to the polycrystalline conductive layer;
forming a second plug within the second opening according to an epitaxial growth method;
forming a single-crystal semiconductor pattern on the first and second plugs and the insulation layer; and
forming a second transistor on the single-crystal semiconductor pattern.

10. The method of claim 9, wherein forming the single-crystal semiconductor pattern comprises:
forming a polycrystalline semiconductor layer on the first and second plugs and the insulation layer; and
crystallizing the polycrystalline semiconductor layer.

11. A method of forming a semiconductor device, the method comprising:
providing a semiconductor substrate having a single-crystal region and a first transistor formed thereon;
forming an interlayer insulation layer on the semiconductor substrate, the interlayer insulation layer comprising a first opening defined therein exposing the single-crystal region;
forming a single-crystal plug within the first opening;
forming a conductive layer on the single-crystal plug and on the interlayer insulation layer;
forming an insulation layer on the conductive layer, the insulation layer comprising a second opening exposing the conductive layer and a third opening exposing the single-crystal plug;
forming a single-crystal semiconductor pattern within the second and third openings and on the insulation layer; and
forming a second transistor on the single-crystal semiconductor pattern.

12. The method of claim 11, wherein forming the single-crystal semiconductor pattern comprises:
forming a polycrystalline semiconductor layer within the second and third openings and on the insulation layer; and
crystallizing the polycrystalline semiconductor layer.

13. A semiconductor device, comprising:
a conductive layer on a semiconductor substrate;
an insulation layer on the conductive layer;
a semiconductor pattern on the insulation layer;
a first plug within the insulation layer electrically connecting the conductive layer to the semiconductor pattern;
a first transistor, wherein the first transistor comprises the semiconductor pattern; and
a body contact electrically connected to the conductive layer.

14. The device of claim 13, further comprising:
an interlayer insulation layer between the conductive layer and the semiconductor substrate; and
a second transistor between the interlayer insulation layer and the semiconductor substrate.

15. The device of claim 13, further comprising:
a plurality of first plugs electrically connected to the conductive layer; and
a plurality of semiconductor patterns,
wherein respective ones of the semiconductor patterns are electrically connected to corresponding ones of the plurality of first plugs.

16. The device of claim 14, wherein the semiconductor substrate comprises an active region, the device further comprising a second plug within a portion of the interlayer insulation layer exposed by the semiconductor pattern, wherein the second plug is electrically connected to the active region.

17. A silicon-on-insulator (SOI) semiconductor device, comprising:
a semiconductor substrate;
at least one SOI structure over the semiconductor substrate, the SOI structure comprising:
a conductive pattern,
an insulation layer on the conductive pattern,
a semiconductor pattern on the insulation layer electrically connected to the conductive pattern through the insulation layer, and
a transistor comprising the semiconductor pattern; and
a body contact electrically connected to the conductive layer.

18. The SOI semiconductor device of claim 17, further comprising a transistor on the semiconductor substrate below the at least one SOI structure.

19. The SOT semiconductor device of claim 17, wherein the SOI structure comprises a plurality of transistors coupled the conductive pattern.

20. The SOI semiconductor device of claim 17, further comprising a plurality of SOT structures in a stacked arrangement.

21. The method of claim 9, further comprising forming a body contact electrically corrected to the polycrystalline conductive layer.

22. The method of claim 11, further comprising forming a body contact electrically connected to the conductive layer.
